(19) United States
(12) Patent Application Publication
(10) Pub. No.: US 2010/0243053 A1
(43) Pub. Date: Sep. 30, 2010

(54) Photovoltaic devices including quantum dot down-conversion materials useful for solar cells and materials including quantum dots

(76) Inventors: Seth Coe-Sullivan, Belmont, MA (US); Peter T. Kazlas, Sudbury, MA (US); Jonathan S. Steckel, Bedford, MA (US); John R. Linton, Concord, MA (US); Maria J. Anc, Groveland, MA (US); John E. Ritter, Westford, MA (US); Marshall Cox, North Haven, CT (US)

Correspondence Address: QD VISION, INC., 313 PLEASANT STREET, 4TH FLOOR, WATERTOWN, MA, 02472, US

(21) Appl. No.: 12/655,073

(22) Filed: Dec. 22, 2009

Related U.S. Application Data
(62) Division of application No. PCT/US2008/008036, filed on Jun. 26, 2008.
(60) Provisional application No. 60/946,382, filed on Jun. 26, 2007.

(51) Int. Cl. H01L 31/00; F28F 7/00

(52) U.S. Cl. 136/259; 165/185

(57) ABSTRACT

A photovoltaic device includes a heat transfer material comprising a dispersion of down-conversion quantum dots in a host medium. In certain embodiments, the host medium comprises a liquid or fluid. In certain embodiments, a heat transfer material comprises a dispersion of down-conversion quantum dots in a host medium comprising one or more heat-transfer fluids. A heat transfer material including quantum dots is also disclosed. Such devices and heat transfer materials can be useful for light energy conversion, e.g., in solar cells. Solar cells are also disclosed.

This application is a continuation application of commonly owned International Application No. PCT/US2008/008036, filed 26 Jun. 2008, which was published in the English language as PCT Publication No. WO 2009/002551 on 31 Dec. 2008. The PCT Application claims priority from commonly owned U.S. Patent Application No. 60/946,382 filed 26 Jun. 2007. The disclosures of each of the foregoing applications are hereby incorporated herein by reference in their entireties.

### TECHNICAL FIELD

The present invention relates to the technical field of photovoltaics, and more particularly to photovoltaic devices including quantum dots.

### BACKGROUND OF THE INVENTION

Development of photovoltaic devices useful for solar cells has progressed tremendously since the introduction of the first silicon photovoltaic (PV) devices as power sources for space satellites in the 1950s. Since then, advancements in materials and fabrication techniques have enabled growth of the solar cell industry not only for space but also for terrestrial applications. For the past two decades PV devices have provided a reliable source of electricity both connected to the grid as well as in isolated off-grid locations. In all applications, efficiency and cost are the two major drivers for PV technology developments.

The highest efficiency solar cells in both terrestrial and space applications are still multi junction III-V devices. Apart from the multi-junction (tandem) cells, where efficiency is increased by stacking complementary cells on top of one another, other parallel approaches have been suggested including hot-carrier cells, creation of multiple electron-hole pairs per photon, thermophotovoltaic conversion, multiple quantum solar cells, and sub-band excitation devices. Many of these proposed techniques focus on optimizing the photon to electron conversion processes to the particulars of the solar spectrum, shown in FIG. 1. (Reference: M. G. Bawendi, A. R. Kortan, M. L. Steigerwald, L. E. Brus, J. Chem. Phys. 1989, 91, 7282)

As illustrated in FIG. 2, efficiency and cost projections for the first-, second-, and third-generation photovoltaic technologies shows the need for substantial reduction of cost per Watt. The theoretical thermodynamic limit of 93% for the conversion of sunlight to electricity and the upper theoretical limit for, for example, single junction devices of 33%, suggests that the performance of solar cells could be improved by a factor of 2 or 3 if different fundamental concepts were used to design the new generation of PVs. (FIG. 2 depicts “Efficiency and cost projections for 1^{st}, 2^{nd}, and 3^{rd}-generation photovoltaic technology (wafers, thin-films, and advanced thin-films, respectively.”, M. A. Green et al., “Third generation photovoltaics: ultra-high conversion efficiency at low cost” Progr. Photovolt: Res. Appl. 2001; 9:123-135. See also the references therein.)

### SUMMARY OF THE INVENTION

The present invention relates to a photovoltaic (PV) device including a wavelength down-conversion material comprising quantum dots. (Wavelength down-conversion materials that include quantum dots are also referred to herein as “quantum dot down-conversion materials” or “QD-DCMs”.) Such device can be useful for light energy conversion, e.g., in solar cells.

In accordance with one aspect of the present invention, there is provided a photovoltaic device including a surface for receiving light energy and a heat transfer material positioned between a source of light energy and the surface for receiving light energy, wherein the heat transfer material comprises a heat transfer material comprising quantum dots and a host medium. In certain preferred embodiments, the heat transfer material can convert the wavelength of at least 30%, and preferably from about 50% to about 90%, and more preferably substantially all, of the ultraviolet light input received by the heat transfer material for energy conversion by the photovoltaic device.

In certain embodiments, the photovoltaic device includes a heat transfer material comprising a dispersion of down-conversion quantum dots in a host medium. In certain embodiments, the host medium comprises a heat transfer material. In certain preferred embodiments, the host medium comprises a liquid or fluid. In certain embodiments, the host medium comprises a heat transfer fluid.

In certain embodiments, a quantum dot comprises a semiconductor composition. In certain embodiments, the semiconductor material comprises a ternary semiconductor composition.

In certain preferred embodiments, a quantum dot comprises a semiconductor composition comprising one or more Group III elements (e.g., aluminum, gallium, indium, thallium, and mixtures thereof), and one or more Group V elements (e.g., nitrogen, phosphorus, arsenic, antimony, or mixtures thereof).

In certain embodiments, a quantum dot comprise InAsₓP₁₋ₓ, wherein 0≦x≦1.

In certain embodiments, a quantum dot comprise InAsₓP₁₋ₓ, wherein 0≦x≦1.

In certain embodiments, a quantum dot comprises InAsₓP₁₋ₓ, a semiconductor with a direct bulk band gap ranging from 0.36 eV when x=1 to 1.27 eV when x=0.

In certain embodiments, a quantum dot includes a passivation material over at least a portion of the QD. A passivation material can comprise an inorganic material and/or an organic material.

In certain embodiments, a quantum dot comprises a core comprising a first semiconductor material and a shell disposed over at least a portion of a surface of the core, wherein the shell comprises a second semiconductor material.

In certain preferred embodiments, the core comprises an III-V semiconductor material. In certain embodiments, the core comprises InAsₓP₁₋ₓ, wherein 0≦x≦1. In certain embodiments, the shell comprises an II-VI semiconductor material. In certain embodiments, for example, the shell comprises zinc and sulfur. In certain embodiments, the shell comprises a ternary II-VI semiconductor material. In certain embodiments, the shell comprises zinc and sulfur and selenium.

In certain embodiments, the quantum dots do not include cadmium, lead, or other heavy metal.

In certain embodiments, the quantum dots are capable of emitting light at a predetermined wavelength in a range from 550 to 1400 nm, sufficient to cover the peak absorption of most single-junction PV solar cells.

In certain embodiments, the quantum dots are capable of emitting light at a predetermined wavelength in a range from 780 nm to 1000 nm.

In certain embodiments, at least a portion, preferably at least half, and more preferably, substantially all, of the down-conversion quantum dots further include one or more ligands on a surface thereof to maintain QD stability and brightness. Examples of preferred ligands include alkyl-amines, thiols, and mild alkyl chain based acids.

In certain preferred embodiments, the heat transfer material contains about 0.1 mg/in² to about 10 mg/in² of down-conversion quantum dots, and preferably from about 0.5 mg/in² to about 3 mg/in² of down-conversion quantum dots.

In certain embodiments, a heat transfer material comprises a dispersion of down-conversion quantum dots in a host medium comprising one or more heat-transfer fluids. In certain embodiments, the dispersion further includes non-polar molecules to tune viscosity.

In certain embodiments, a photovoltaic device includes a heat transfer material taught herein.

In certain embodiments, the photovoltaic device further includes a concentrator member positioned between the photovoltaic device and a light source to focus or concentrate light into the photovoltaic device.

In certain embodiments, a photovoltaic device useful for solar energy conversion including a surface for receiving light energy, comprises a layer comprising a quantum dot down-conversion material disposed over at least a portion of the surface for receiving light energy, and a heat transfer material positioned between a source of light energy and the layer, wherein the heat transfer material comprises a heat transfer material comprising quantum dots dispersed in a host medium.

In a PV device in accordance with the invention including a heat transfer material comprising a dispersion of down-conversion quantum dots in a heat-transfer fluid and further including a concentrator member positioned between the light source and heat transfer material, for example, such heat transfer material can enhance the efficiency and self-cool the device to allow an improvement in concentration ratios, and hence a drop in $/Watt.

In certain preferred embodiments, the photovoltaic device includes a down conversion layer over at least a portion of a top surface of the device, wherein the layer comprises a first quantum dot down-conversion material, and a heat transfer material comprising a second quantum dot down-conversion material. Preferably, the heat transfer material is positioned between a light source and the down conversion layer. In certain embodiments, the first and second QD-DCMs can be the same or substantially the same. In certain embodiments, the first and second QD-DCMs can be different.

In certain embodiments, the PV device comprises a single-junction device.

In certain embodiments, the PV device comprises a multiple-junction device.

In certain embodiments, the quantum dots included in a quantum dot down-conversion material do not include cadmium.

In accordance with an embodiment of the invention, heavy metal-free quantum dot materials, preferably having high-efficiency, are included in a down conversion material for inclusion in a layer (e.g., filter, film, coating, etc.) that is adapted for PV applications.

In accordance with another aspect of the present invention, there is provided a heat transfer material including quantum dots. In certain preferred embodiments, the heat transfer material comprises a heat transfer fluid comprising quantum dots. In certain more preferred embodiments, the heat transfer material comprises a quantum dot down-conversion material. In certain embodiment, the quantum dots do not include a heavy metal, including, but not limited to, cadmium and lead.

In certain embodiments, a heat transfer material comprises a dispersion of down-conversion quantum dots in a host medium comprising one or more heat-transfer fluids.

Heat transfer fluids are well known and available from a number of sources. In certain preferred embodiments, the heat transfer fluid is at least 30%, preferably at least 50%, more preferably at least 70%, and most preferably at least 80%, optically transparent to ultraviolet light and the light emitted by the quantum dots.

In certain embodiments, non-polar molecules are included in a heat transfer fluid to tune viscosity.

In certain embodiments, a quantum dot comprises a semiconductor composition. In certain embodiments, the semiconductor material comprises a ternary semiconductor composition.

In certain preferred embodiments, a quantum dot comprises a semiconductor composition comprising one or more Group III elements (e.g., aluminum, gallium, indium, thallium, and mixtures thereof), and one or more Group V elements (e.g., nitrogen, phosphorus, arsenic, antimony, or mixtures thereof).

In certain embodiments, a quantum dot comprise InAsₓP₁₋ₓ, wherein 0≦x≦1.

In certain embodiments, a quantum dot comprise InAsₓP₁₋ₓ, wherein 0≦x≦1.

In certain embodiments, a quantum dot comprises InAsₓP₁₋ₓ, a semiconductor with a direct bulk band gap ranging from 0.36 eV when x=1 to 1.27 eV when x=0.

In certain embodiments, a quantum dot includes a passivation material over at least a portion of the QD. A passivation material can comprise an inorganic material and/or an organic material.

In certain embodiments, a quantum dot comprises a core comprising a first semiconductor material and a shell disposed over at least a portion of a surface of the core, wherein the shell comprises a second semiconductor material.

In certain embodiments, the core comprises an III-V semiconductor material. In certain embodiments, the core comprises InAsₓP₁₋ₓ, wherein 0≦x≦1. In certain embodiments, the shell comprises an II-VI semiconductor material. In certain embodiments, for example, the shell comprises zinc and sulfur. In certain embodiments, the shell comprises a ternary II-VI semiconductor material. In certain embodiments, the shell comprises zinc and sulfur and selenium.

In certain embodiments, the quantum dots do not include cadmium, lead, or other heavy metal.

In certain embodiments, the quantum dots are capable of emitting light at a predetermined wavelength in a range from 550 to 1400 nm, sufficient to cover the peak absorption of most single-junction PV solar cells.

In certain embodiments, a quantum dot is capable of emitting light at a predetermined wavelength in a range from 780 nm to 1000 nm.

In certain embodiments, a quantum dot includes one or more ligands attached to a surface thereof.

In certain embodiments, at least a portion, preferably at least half, and more preferably, substantially all, of the down-conversion quantum dots further include one or more ligands on a surface thereof to maintain QD stability and brightness. Examples of preferred ligands include alkyl-amines, thiols, and mild alkyl chain based acids.

In accordance with another aspect of the present invention, there is provided a solar cell including a heat transfer material taught herein.

In accordance with another aspect of the present invention, there is provided a solar cell including a photovoltaic device taught herein.

The foregoing, and other aspects described herein all constitute embodiments of the present invention.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### BRIEF DESCRIPTION OF THE DRAWINGS

In the drawings,

FIG. 1 graphically illustrates a solar reference spectrum.

FIG. 2 graphically presents efficiency and cost projections from the literature for the first-, second-, and third-generation photovoltaic technologies.

FIG. 3 graphically illustrates integrated emission intensity of a sample of packaged QDs exposed to the UV for extended period of time.

FIGS. 4(A)-(C) illustrate examples of various embodiments of different architectures of photovoltaic devices.

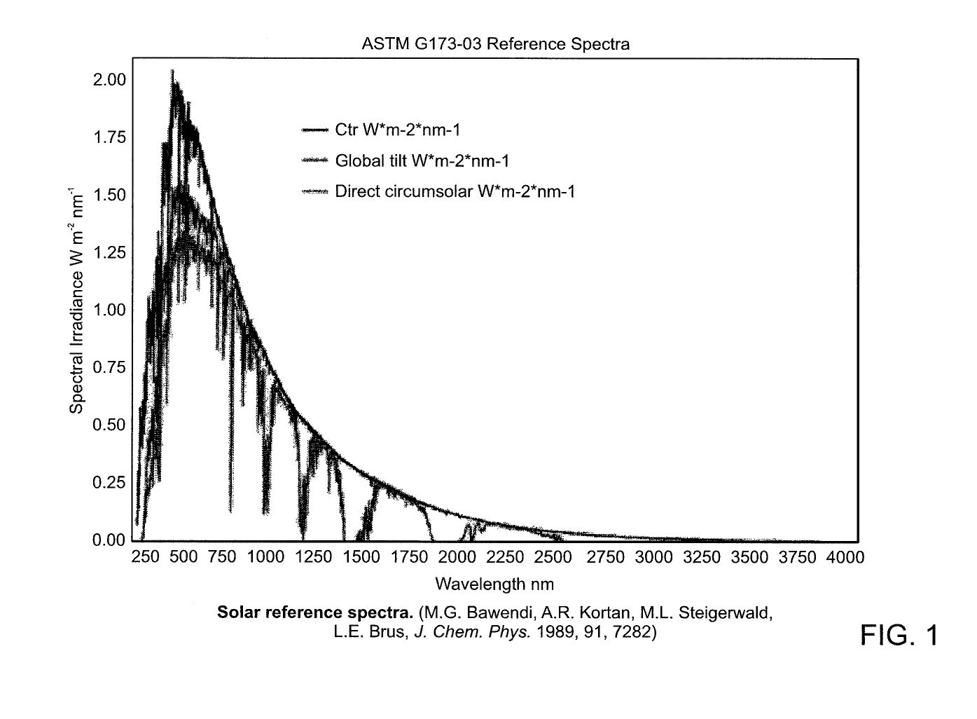

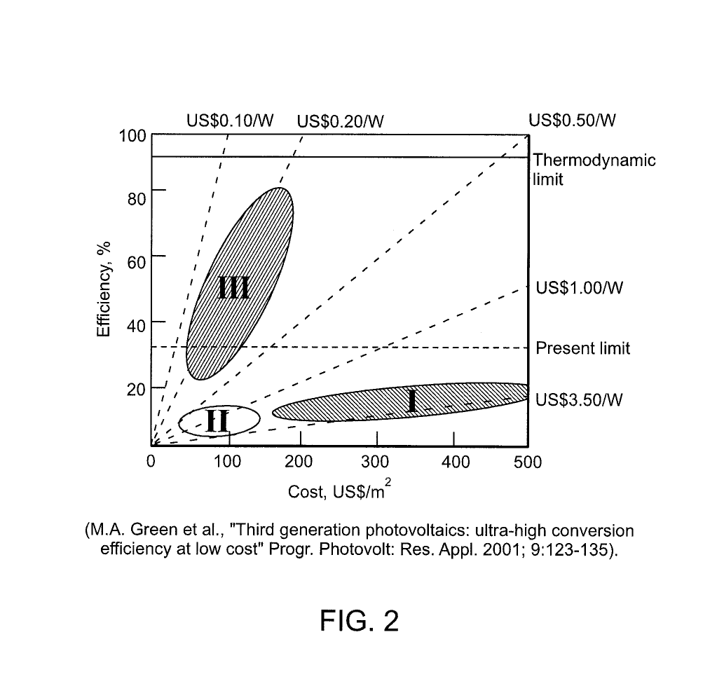

The attached figures are simplified representations presented for purposes of illustration only; the actual structures may differ in numerous respects, particularly including the relative scale of the articles depicted and aspects thereof.

For a better understanding to the present invention, together with other advantages and capabilities thereof, reference is made to the following disclosure and appended claims in connection with the above-described drawings.

### DETAILED DESCRIPTION OF THE INVENTION

A photovoltaic device includes a heat transfer material comprising a dispersion of down-conversion quantum dots in a host medium. In certain embodiments, the host medium comprises a liquid or fluid. In certain embodiments, a heat transfer material comprises a dispersion of down-conversion quantum dots in a host medium comprising one or more heat-transfer fluids. Such device can be useful for light energy conversion, e.g., in solar cells. A heat transfer material including quantum dots is also disclosed.

A wavelength down-conversion material useful in the present inventions includes quantum dots (QDs). In preferred embodiments, quantum dots comprise quantum confined semiconductor nanocrystals.

The tunability of quantum-confined semiconductor nanocrystals (e.g., including, but not limited to, quantum dots comprising PbS) in the NIR range of the spectrum from 780 nm to 1800 nm, and absorption in solid QD films or dispersions are useful in fabrication of devices involving high sensitivity in the near infrared (NIR).

In certain embodiments of the invention, there are provided photovoltaic devices for use in solar cells, wherein the photovoltaic devices includes a heat transfer material including quantum dot down-conversion materials (QD-DCMs). In certain embodiments, a photovoltaic device for use in a solar cell includes a film including down-conversion quantum dots and a heat transfer fluid taught herein. In certain embodiments, solar cells are single-junction type solar cells. Use of QD-DCMs in single-junction solar cells will approach and/or surpass multi-junction solar cell performance.

In certain embodiments, the PV system design is planar.

In certain embodiments of the invention, a PV device including a wavelength down-conversion material between a source of light energy and the top surface of the PV device will improve planar PV performance. In certain embodiments, the down-conversion material will comprise a host material including quantum dots. In certain embodiments, a PV device further includes down-conversion component comprising a film including quantum dots.

In certain embodiments, the system design comprises a concentrator PV architecture.

In certain embodiments of the invention, a down-conversion fluid comprising quantum dots and a liquid host material is included in a concentrator PV system to remove heat from the system. In such embodiments, the efficiency of the system can be increased compared to a system not including the down-conversion fluid including quantum dots and a liquid host material.

In certain embodiments, the quantum dots included in the down-conversion material or down-conversion fluid do not include cadmium.

In certain embodiments, the down conversion material comprises a film including cadmium-free quantum dots. In certain embodiments the film is tailored for PV application.

In accordance with an embodiment of the invention, heavy metal-free quantum dot materials, preferably having high-efficiency (e.g., >50%, preferably >70%), are included in a down-conversion component (e.g., filter, film, coating, etc.) that is adapted for PV applications.

In accordance with another embodiment of the invention, there is provided a heat transfer fluid comprising quantum dots.

In accordance with a further embodiment of the invention, there is provided a down-conversion component including quantum dots and a heat transfer fluid.

In accordance with yet a further embodiment of the invention, there is provided a PV system including a down-conversion material comprising quantum dots and a heat transfer material.

In certain embodiment, the quantum dots do not include a heavy metal, including, but not limited to, cadmium and lead.

In certain embodiments, a quantum dot comprises InAsₓP₁₋ₓ, a ternary semiconductor with a direct bulk band gap ranging from 0.36 eV when x=1 to 1.27 eV when x=0. Quantum dots comprising this ternary semiconductor composition can have a QD emission tuning range from 550 to 1400 nm, sufficient to cover the peak absorption of most single-junction PV solar cells. One report was found in the literature showing the successful synthesis of InAsₓP₁₋ₓ QDs. See, for example, Kim S-W, Zimmer J P, Ohnishi S, Tracy J B, Frangioni J V, Bawendi M G. Engineering InAsₓP₁₋ₓ/InP/ZnSe III-V Alloyed Core Shell Quantum Dots for the Near-Infrared. Journal of the American Chemical Society 2005, 127: 10526-10532, which is hereby incorporated herein by reference in its entirety. (The reported material was optimized for biological applications with quantum yields below 5% and emission wavelengths around 800 nm.) In certain embodiments, 0≦x≦0. Large particles of InAs will provide emission around 1400 nm, while the InAsₓP₁₋ₓ, alloy can be tuned to efficiently emit at a predetermined wavelength in a range from 780 nm to 1000 nm. The quantum dots comprising InAs or InAsₓP₁₋ₓ alloy preferably further include an alloy shell material of ZnSeS on at least a portion of the InAs and InAsₓP₁₋ₓ core materials. Preferably, the QD materials have high quantum efficiency (e.g., >85%) when dispersed in a liquid medium.

High quantum efficiencies (e.g., >85%) of Cd-based quantum dots in solution have been achieved. Tailoring the chemical compatibility of quantum dot surfaces with the chemical nature of the material in which it is dispersed (whether solvent, solid, or a hybrid medium) enables QDs to be readily dispersed therein while maintaining quantum efficiencies of over 50% in the solid state. In certain embodiments, as-synthesized quantum yields of the QDs in solution involves engineering the QD sample such that it is miscible with the desired solvent system.

In certain embodiments, transition from a liquid to a solid dispersion presents a significant challenge to preserving QD quantum efficiencies. It has been determined that the speed of this transition can affect quantum efficiency. Preferably, curing is carried out at a rate that “locks” the QDs into place before aggregation or other chemical effects can occur.

In certain embodiments of the invention for PV applications including a down-conversion material comprising a film including quantum dots, the QDs will be dispersed in an inorganic film. In certain embodiments, the inorganic film comprises an inorganic oxide, e.g., SiO₂, TiO₂ Chemically matching the QDs to the inorganic host material and control of the speed of “cure” can improve the efficiency of down-conversion material. Other examples of a host-material for a down-conversion material include long-lived organic host materials such as polysiloxanes.

In certain embodiments, QDs are dispersed in micro-droplets of a quantum dot solvent or other liquid dispersion medium or an organic host material that maintain quantum efficiency. The hybrid approach can be seen as an attempt to combine the high quantum efficiency of the liquid state with the structural simplicity of a film. The QDs will be in a micro-environment that not only maintains the emission efficiency, but in a film that can be easily processed and have a long life in a PV application.

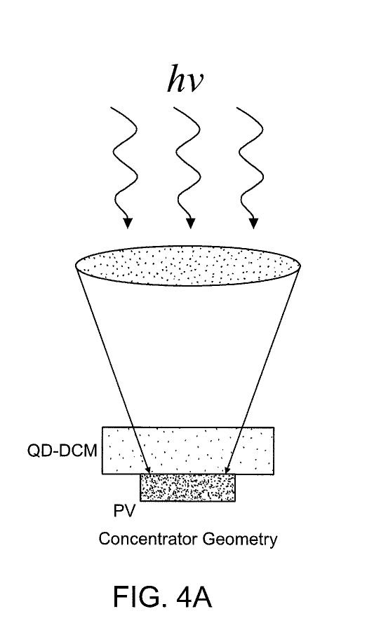

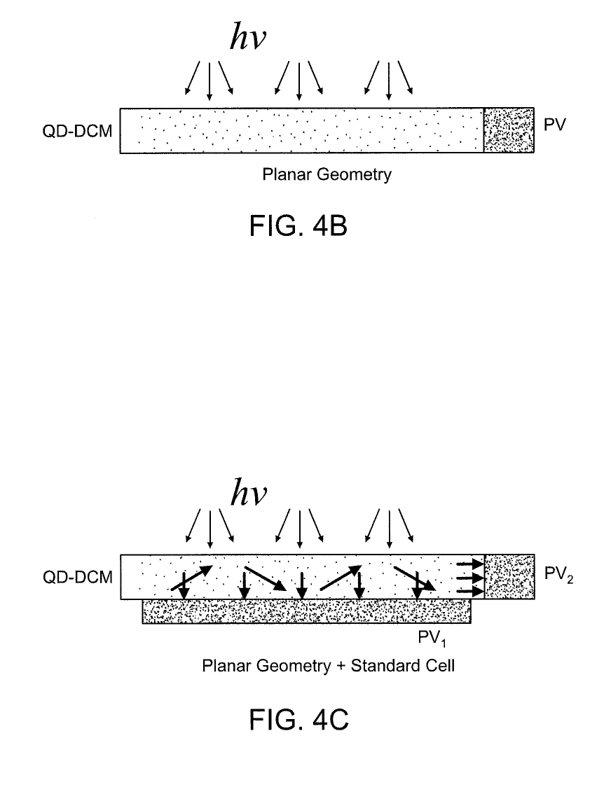

FIG. 4 provides configurations of examples of various embodiments of photovoltaic devices including quantum dot down-conversion material (QD-DCM) for use in solar cells. In A) solar radiation is concentrated through a fresnel lens onto a small area, high efficiency crystalline PV. The QDM converts the highest energy photons into photons which are optimized to maximize the conversion efficiency of the PV cell. The energy is lost to heat in the QDM, rather than in the PV. In the planar geometries of B) and C), the large area QD-DCM absorbs incident solar radiation, converts it to more useful lower energy photons, which are then incident upon the PV cells. Again the heat is dissipated in the QDs rather than the PVs. In C), multiple PVs of different bandgaps are used to get the additional benefits of a multijunction PV cell, leveraging the tunable bandgaps of the QDs.

In certain embodiments, QD-DCMs will be included in a PV device having a concentrator geometry. In certain embodiments, QD-DCMS are included in a PV device having a planar PV geometry. In a PV device useful for a solar cell that employs a light concentrator (an example of which is shown in FIG. 4(A)), light is focused onto a small photovoltaic area for conversion into electricity. As a result of this concentration the solar-cell area required to harness the light is significantly decreased, allowing for the use of more expensive and typically more efficient photovoltaic materials. A drawback to this design is the generation of excessive heat due to the inefficiency of current photovoltaic materials to harness higher energy photons. Each high-energy photon results in energy generation intrinsic to that material, plus additional energy that converts to heat, necessitating heat-sinking technologies to keep the photovoltaic cool enough to continue to function. Quantum dots are well known to have an absorption spectrum that absorbs strongly in energies higher than their band gap, which itself is tunable across all wavelengths pertinent to solar emission. This combined with their colloidal nature makes them uniquely suited to concentrator heat-sinking. In the geometry shown in FIG. 4(A), a QD solution is placed in the light path between the concentrator and the photovoltaic cell. High energy light of a predetermined wavelength is absorbed by the QDs, resulting in extremely uniform QD light emission plus heat generation from higher energy photons, warming the liquid. The remaining photons of the desired energies pass unimpeded through the solution to the photovoltaic cell beneath, leaving the QD solution to be cooled by well-established techniques that can be readily ascertained by one or ordinary skill in the relevant art, such as convective or reservoir cooling.

An example of a simple system is a “thermosiphon” which is based on convective movement of the liquid in a closed loop, as described at http://www.answers.com/topic/thermosiphon?cat=technology. As described at such site, convective movement begins when the liquid in the loop is heated, causing the liquid to expand and become less dense, and thus more buoyant than the cooler liquid in the bottom of the loop. Convection moves heated liquid upwards in the system as it is simultaneously replaced by cooler liquid returning by gravity. In many cases the liquid flows easily because the thermosiphon is designed to have very little hydraulic resistance. At least the portion of the loop including the heat transfer fluid including down-conversion quantum dots that is positioned between the light source and the photovoltaic device is preferably constructed from a material that is transparent to the light passing into the heat transfer fluid and to the wavelengths passing out of the heat transfer fluid to the photovoltaic device. Examples of such materials include UV-Visible wavelength transparent glasses, quartz, and other UV-Visible wavelength materials.

Optionally, a second quantum dot down-conversion material is disposed between the heat transfer material and the photovoltaic device to down-convert at least a portion, and preferably substantially all, of any unconverted photons passing into the device. In certain embodiments, the second quantum dot down-conversion material is included as a layer over at least a portion of the surface of the photovoltaic device, In certain embodiments, the down-conversion quantum dots included in the heat transfer material have the substantially the same size and composition as those included in the second quantum dot down-conversion material.

In simple planar geometries (e.g., an example of which is shown in FIG. 4(B)), QDs are dispersed in a solid film and can serve as a concentrator. This geometry is uniquely suited to both direct and diffuse light irradiating the photovoltaic device. As light is incident on the device, photons sufficiently energetic to excite the QDs do so, resulting again in specific photon generation and heat. The heat in this case does not affect operation in that it is not concentrated. As much as 80% of the photons generated are wave-guided, or focused, due to total internal reflection in the film to the boundaries of the device, where this light may excite a photovoltaic material uniquely tuned to absorb the pure QD light emission.

This device may also be used to enhance the energy generation in standard photovoltaic cells, an example of one configuration of which is shown in FIG. 4(C), combining the photovoltaic properties of geometry 6(B) with the band-pass properties of geometry 4(A).

The application of QD-DCMs to PV systems can enhance the performance of both planar and concentrator-based PV systems. (Several research groups have demonstrated numerical simulations that show that significant gains in short circuit current (6-25%) can be realized by the application of down-conversion films to off-the-shelf PV cells.) For planar PV, QD-DCMs can concentrate diffuse sun light and waveguide converted photons to optimized PV cells thereby enabling smaller and flatter concentrator PV packages for broader use, or even rollable. For traditional concentrator geometries, QD down-conversion fluids can be used to both convert high energy photons as well as dissipate power away from the PV cell, improving efficiencies at high concentrator ratios.

In certain embodiments, quantum confined semiconductor nanocrystals comprise InAsₓP₁₋ₓ, wherein 0≦x≦1. InAsₓP₁₋ₓ, is a III-V semiconductor, which is inherently a more covalently bonded crystal compared to a II-VI semiconductor such as CdSe. This difference stems from the chemical reactivity of the precursors that compose III-V semiconductors. In general, III-V materials associate more strongly with the elements oxygen, nitrogen, sulfur, and phosphorous as compared to the II-VI molecular precursors. Thus, more reactive III-V precursors are required to get semiconductor formation at 200-300° C. in solution. The higher reactivity of the precursors leads to concurrent nucleation and growth processes during colloidal synthesis and results in the broad size distributions and lower quantum efficiencies typically associated with III-V QDs. Thus, in order to produce III-V materials with narrow size distributions, high stability and high quantum efficiencies, the nucleation and growth processes will be preferably separated and controlled. In certain embodiments, molecular precursors with different reactivities will be utilized. In certain embodiments, nucleation and growth events during the reaction will be managed by varying the concentration of the capping molecules. In certain embodiments, different capping molecules can be used.

In certain embodiments, a semiconductor shell material for the InAsₓP₁₋ₓ comprises ZnS due to its large band gap leading to maximum exciton confinement in the core. The Zinc Blende phase is adopted by both semiconductors ZnS and InAsₓP₁₋ₓ. The lattice mismatch between InP and ZnS is about 8%. In certain embodiments, based on the presence of As doped into the InP and the affect of the doping on the mismatch to some degree, a small amount of Se can be added to the initial shell growth. It is expected that the addition of Se can help to grow an improved (e.g., thicker) shell on InAsₓP₁₋ₓ, than can be obtained without the addition of Se. This is based on the mismatch between InP and ZnSe being only 3% and the mismatch between InAs and ZnSe being about 6%. The shell can be prepared be a method comprising doping Se into the Zn and S precursors during initial shell growth in decreasing amounts to provide a graded shell, rich in Se at the beginning fading to 100% ZnS at the end of the growth phase.

Solutions comprising QDs are much more efficient than QDs packed together in the solid state. QDs that are closely-packed experience dipole-dipole interdot interactions. This long-range resonance transfer of electronic excitations from the more electronically confined states of small QDs to the higher excited states of larger QDs leads to significantly decreased quantum yields compared to QDs dispersed in solution. This electronic energy transfer allows the excited states to migrate in the film from one QD to another, and some percentage of the time non-radiatively recombine on QDs that are poorly passivated or contain surface defects. Ligand engineering or selection can be used to space the QDs apart from one another in the solid state to inhibit energy transfer from QD to QD. Ligands that are solvated reside in low energy minima on the QD surface, optimizing bonding, but ligands that reside on QDs in the solid state undergo strain and as a result surface passivation may be degraded and the quantum yield may drop significantly.

The most efficient and stable environment for QDs is in a solution where the QDs are dispersed in a liquid host material that contains an excess of capping ligands. In certain embodiments, QD solutions are included in solar cell concentrators taking advantage of down-conversion. QDs absorb all wavelengths of light higher in energy than the band gap and then emit that light in the form of a saturated band of light making them the most ideal down-conversion materials currently known. In certain embodiments, solution quantum efficiencies of Cd-based QD materials as high as 95% and the peak emission can be tuned to any desired wavelength to within a couple of nanometers. These solutions include a mixture of heat-transfer fluids, non-polar molecules to tune viscosity, and ligands to maintain QD stability and brightness such as alkyl-amines, thiols, and mild alkyl chain based acids.

Heat transfer fluids are well known and available from a number of sources. In certain preferred embodiments, the heat transfer fluid is at least 50%, preferably at least 70%, and most preferably, at least 80%, optically transparent to ultraviolet light and the light emitted by the quantum dots.

In certain embodiment, a down-conversion material comprises a solid state host material including QDs. In certain host material formulations, QDs will include one or more ligands attached to a quantum dot surface wherein the ligands are chemically compatible with the QDs and the host material. This can provide for maximum stability and efficiency of the QD films. In certain embodiments, QD-DCMs will be adapted for use with PV cells in the range of 0.7-1.4 eV. In certain embodiments, the PV will have a planar PV geometry. In certain embodiments, the PV system will include an optical system for light concentration in either classical or planar form. In certain embodiments, the PV module assembly will include packaging. In certain embodiments, a PV system will include a QD-DCM comprising InAsP-based QD-DCMs.

InAsₓP₁₋ₓ QD materials will be synthesized by a method comprising synthesizing InP and doping As therein to make InAsₓP₁₋ₓ.

In certain embodiments, InAs will be used when an emission past 1100 nm is desired. In certain embodiments, InAsₓP₁₋ₓ will be used to obtain emission wavelengths higher in energy.

In certain embodiments, a Cd-based QD material with an efficiencies of greater than 90% will be included in a solid host material. In certain embodiments, a Cd-based QD material will be included in a liquid.

In certain embodiments, the host material (liquid or solid) of the heat transfer material is selected to a) maintain the QY of the dots, b) provide a stable, long life environment for the dots in a PV application, and c) manage the heat generated in the QD layer by high energy photons.

In certain embodiments, a PV system will further include a heat removal system to remove heat from the heat transfer material. Liquid systems have the advantage that passive or low-energy QD solution circulation systems could be employed, while solid films may use conduction away from the solar cell.

In certain embodiments, various types of single-junction solar cells and combinations thereof will be integrated into compact concentrator designs suitable for broad use.

In certain embodiments, a PV system will further include an optical system. Preferably, for a PV system with a planar, thin geometry, the optical coupling through the QD-DCM will be maximized and the re-absorption losses minimized. In certain embodiments, the PV system will comprise a configuration that includes more than one PV cell to collect additional spectral components. As an example, as discussed earlier, in one planar configuration one PV cell mounted on the side of the QD-DCM can be used to capture the waveguided light while another PV cell can be used to capture unabsorbed light, thereby increasing overall module efficiency. For concentrator PV systems, the requirements of minimizing compact module size and maximizing heat transfer in the QD down-conversion fluid will be balanced using both passive and active cooling techniques while maintaining high efficiency down-conversion.

PV systems in accordance with the invention can be operated under various illumination conditions (e.g., under diffuse sunlight or direct sunlight).

In certain embodiments, the QD composition and geometry are designed to optimize the red-shift of photoluminescence (PL) in order to minimize self-absorption and carrier thermalization losses within individual QDs. Self-absorption will also be quantified for a range of QD concentrations, host material optical properties, and temperatures.

The flow of energy in a model system consisting of the down-converter/concentrator and a PV cell can be mapped. This system can be further optimized by the skilled artisan with regard to efficient heat transfer between the PV cell and the host material of the down-converter/concentrator.

A nanocrystal is a nanometer sized particle, e.g., in the size range of up to about 1000 nm. In certain embodiments, a nanocrystal can have a size in the range of up to about 100 nm. In certain embodiments, a nanocrystal can have a size in the range up to about 20 nm (such as about 1, 2, 3, 4, 5, 6, 7, 8, 9, 10, 11, 12, 13, 14, 15, 16, 17, 18, 19, or 20 nm). In certain preferred embodiments, a nanocrystal can have a size less than 100 Å. In certain preferred embodiments, a nanocrystal has a size in a range from about 1 to about 6 nanometers and more particularly from about 1 to about 5 nanometers. The size of a nanocrystal can be determined, for example, by direct transmission electron microscope measurement. Other known techniques can also be used to determine nanocrystal size.

Nanocrystals can have various shapes. Examples of the shape of a nanocrystal include, but are not limited to, sphere, rod, disk, tetrapod, other shapes, and/or mixtures thereof.

In certain preferred embodiments, QDs comprise inorganic semiconductor material which permits the combination of the soluble nature and processability of polymers with the high efficiency and stability of inorganic semiconductors. Inorganic semiconductor QDs are typically more stable in the presence of water vapor and oxygen than their organic semiconductor counterparts. Because of their quantum-confined emissive properties, their luminescence can be extremely narrow-band and can yield highly saturated color emission, characterized by a single Gaussian spectrum. Finally, because the nanocrystal diameter controls the QD optical band gap, the fine tuning of absorption and emission wavelength can be achieved through synthesis and structure change.

In certain embodiments, inorganic semiconductor nanocrystal quantum dots comprise Group IV elements, Group II-VI compounds, Group II-V compounds, Group III-VI compounds, Group III-V compounds, Group IV-VI compounds, Group compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TIN, TIP, TIAs, TlSb, PbO, PbS, PbSe, PbTe, alloys thereof, and/or mixtures thereof, including ternary and quaternary alloys and/or mixtures.

The most developed and characterized QD materials to date are II-VI semiconductors, including CdSe, CdS, and CdTe. CdSe, with a bulk band gap of 1.73 eV (716 nm), can be made to emit across the entire visible spectrum with narrow size distributions and high emission quantum efficiencies. Roughly, for example, 2 nm diameter CdSe QDs emit in the blue while 8 nm diameter particles emit in the red. A QD comprising a different inorganic semiconductor with a different band gap alters the region of the electromagnetic spectrum in which the QD emission can be tuned. For example, the smaller band gap semiconductor CdTe (1.5 eV, 827 nm) can access deeper red colors than CdSe. Another well studied and characterized QD material system is the lead containing semiconductors, PbSe and PbS. PbS with a band gap of 0.41 eV (3027 nm) can be tuned to emit from 800 to 1800 nm. It is theoretically possible to design an efficient and stable inorganic QD emitter to emit at any desired wavelength from the UV to the NIR.

Semiconductor QDs grown in the presence of high-boiling organic molecules, referred to as colloidal QDs, have yielded to date among the highest quality nanoparticles for light-emission applications. Such synthetic approach involves the rapid injection of molecular precursors into a hot solvent (300-360° C.), which results in a burst of homogeneous nucleation. The depletion of the reagents through nucleation and the sudden temperature drop due to the introduction of the room temperature solution of reagents minimizes further nucleation. The initial size distribution is determined by the time over which the nuclei form and grow based on the fact that the growth of any one QD is similar to all others. This synthesis technique was first demonstrated by Murray and co-workers, entitled “Synthesis and Characterization of Nearly Monodispersed CdX (X═S, Se, Te)Semiconductor Nanocrystallites” J. Amer. Chem. Soc., 1993 (115) 8706, for the synthesis of II-VI semiconductor QDs by high-temperature pyrolysis of organometallic precursors (dimethylcadmium) in coordinating solvents (tri-n-octylphosphine (TOP) and tri-n-octylphosphine oxide (TOPO)). This work was based on the seminal colloidal work by LaMer and Dinegar, entitled “Theory, Production and Mechanism of Formation of Monodispersed Hydrosols”, J. Amer. Chem. Soc., 1950 (72) 4847, who introduced the idea that lyophobic colloids grow in solution via a temporally discrete nucleation event followed by controlled growth on the existing nuclei.

The ability to control and separate both the nucleation and growth environments is in large part provided by selecting the appropriate high-boiling organic molecules used in the reaction mixture during the QD synthesis. The high-boiling solvents are typically organic molecules made up of a functional head including, for example, a nitrogen, phosphorous, or oxygen atom, and a long hydrocarbon chain. The functional head of the molecules attaches to the QD surface as a monolayer or multilayer; these attached molecules are also referred to as capping groups. The capping molecules present a steric barrier to the addition of material to the surface of a growing crystallite, significantly slowing the growth kinetics. It is desirable to have enough capping molecules present to prevent uncontrolled nucleation and growth, but not so much that growth is completely suppressed.

This colloidal synthetic procedure for the preparation of semiconductor QDs provides a great deal of control and as a result the synthesis can be modified to achieve the desired peak wavelength of emission as well as a narrow size distribution. This degree of control is based on the ability to change the temperature of injection, the growth time, as well as the composition of the growth solution. By changing one or more of these parameters the size of the QDs can be engineered across a large range while maintaining good size distributions.

Semiconductor QDs such as CdSe are covalently bonded solids with four bonds per atom, which have been shown to retain the bulk crystal structure and lattice parameter. At the surface of a crystal, the outermost atoms do not have neighbors to which they can bond, generating so called dangling bonds, which give rise to surface states of different energy levels that lie within the band gap of the semiconductor. Surface rearrangements take place during crystal formation to minimize the energy of these dangling bonds, but because such a large percentage of the atoms that make up a QD are on the surface (e.g., >75% to <0.5% for QDs<1 nm to >20 nm in diameter, respectively), the effect of these dangling bonds on the emission properties of semiconductor QDs is quite large. The surface states lead to non-radiative relaxation pathways, and thus a reduction in the emission efficiency or quantum yield (QY).

When molecules are chemically bound to the surface of a QD, they help to satisfy the bonding requirements of the surface atoms, eliminating many of the surface states and corresponding non-radiative relaxation pathways. This results in QDs with good surface passivation and higher QY as well as higher stability than QDs with poor surface passivation. Thus, design and control of the growth solution and processing can achieve good passivation of the surface states and result in high QYs. Furthermore, these capping groups can play a role in the synthetic process as well by mediating particle growth and sterically stabilizing the QDs in solution.

An effective, if not the most effective, method for creating QDs with high emission efficiency and stability is to grow an inorganic semiconductor shell onto QD cores. A core-shell type composite rather than organically passivated QDs (not having a core-shell structure) is desirable for incorporation into solid-state structures, like a solid state QD-LED device, due to their enhanced photoluminescence (PL) and electroluminescence (EL) quantum efficiencies and a greater tolerance to the processing conditions necessary for device fabrication. The inorganic shell passivates surface electronic states to a far greater extent than organic capping groups. Examples of inorganic semiconductor materials for use in a shell include, but are not limited to, Group IV elements, Group II-VI compounds, Group II-V compounds, Group III-VI compounds, Group III-V compounds, Group IV-VI compounds, Group compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TIN, TIP, TlAs, TlSb, PbO, PbS, PbSe, PbTe, alloys thereof, and/or mixtures thereof, including ternary and quaternary alloys and/or mixtures.

When a shell of a larger band gap material is grown onto a core QD, for example ZnS (band gap of 3.7 eV) onto CdSe, the majority of the surface electronic states are passivated and a 2 to 4 fold increase in QY is observed. An early high-quality QD core-shell system that was made and fully characterized was in fact a shell of ZnS grown onto CdSe. The presence of a shell of a different semiconductor (in particular one that is more resistant to oxidation) on the core also protects the core from degradation. When illuminated for long periods of time in the presence of water and oxygen (ambient conditions), the quantum efficiency of core-shell QDs decreases significantly less as compared to bare QDs (QDs with no shell) and organic dyes (which photobleach readily).

QDs with core-shell structures are preferred. In QD core-shell development, the crystal structure of the core and shell material as well as the lattice parameter mismatch between the two are important considerations. The lattice mismatch between CdSe and ZnS is 12% which is considerable, but because only a couple of atomic layers (1 to 6 monolayers) of ZnS are grown onto CdSe the lattice strain is tolerated. The lattice strain between the core and shell materials scales with the thickness of the shell. As a result, a shell that is too thick will cause dislocations at the material interface and eventually break off of the core. Doping the ZnS shell with Cd can relieve some of this strain, and as a result thicker shells of CdZnS can be grown. The effect is similar to transitioning more gradually from CdSe to CdS to ZnS (the lattice mismatch between CdSe and CdS is about 4% and that between CdS and ZnS about 8%), which provides for more uniform and thicker shells and therefore better QD core surface passivation and higher quantum efficiencies.

While core-shell particles exhibit improved properties compared to core-only systems, further surface passivation with organic ligands further improves quantum efficiency of core-shell QDs. This is due to the fact that the particles are smaller than the exciton Bohr radius, and as a result the confined excited-state wavefunction has some probability of residing on the surface of the particle even in a core-shell type composite. Strong binding ligands that passivate the surface are therefore crucial for making the most stable and efficient core-shell QD material.

Inorganic semiconductor nanocrystals or quantum dots (QDs) are preferably synthesized by solution phase synthesis. Typical semiconductors for visible light emitting QDs are CdSe, CdTe, CdS, and CdSeS. The wavelength of emission is determined by the choice of materials and the size of the nanoparticles, and can be fine tuned by adjusting process conditions, which also have significant impact on the shape of the nanoparticles.

In brief, the QD growth process consists of the rapid introduction of precursors into a high-boiling organic solvent to form nuclei, followed by the growth of those nuclei to create nanoparticles. These core nanoparticles, typically 2 to 12 nm in diameter, are then passivated and protected by the growth of several monolayers of an inorganic semiconductor shell such as ZnS. A core-shell type composite rather than organically passivated core type QDs are desirable in solid state QD-LED devices due to their enhanced photoluminescent and electroluminescent quantum efficiencies and a greater tolerance to the processing conditions necessary for device fabrication. When the QDs are synthesized in an organic solvent such as tri-octylphosphine or oleylamine, the surface is passivated by organic solvent molecules, meaning that the functional head of an organic molecules is associated with the surface of the nanocrystals, while the long hydrocarbon-chain tail is associated with the solvent in which the QDs are dispersed. This feature of the QDs allows them to be dispersed into non-polar solvents such as hexane, chloroform, or toluene. The ability to process QDs using solution phase techniques provides ease of device fabrication in laboratory conditions, and moreover enables large area, low cost device fabrication methods to be applicable in a future commercialization phase. QDs synthesized using colloidal techniques as described above can exhibit highly saturated color emission with typical full-width-at-half-maximums (FWHM) of less than 30 nm. The number of accessible emission colors is virtually unlimited, due to the fact that the QD peak emission can be tailored by selecting the appropriate material system and size of the nanoparticles. FIG. 4 shows examples of QD emission spectra and the CIE color diagram illustrating the potential for fine color tuning of QDs.

The above processes for synthesizing Cd-based QDs can produce QDs having solution quantum yields on the order of 70-80%, with peak emission wavelength reproducibility within +/−2% and narrow peak emissions.

Preferably. QDs are synthesized and processed in an air-free environment.

QD-DCMs can be analyzed by chemical and solid state characterization techniques. For example, high resolution transmission electron microscopy (HRTEM) can provide a direct look at the size distribution and morphology of our QDs and in combination with X-ray diffraction (XRD) can probe the extent of crystallinity in our samples. Wavelength dispersive spectroscopy (WDS) and X-ray photoelectron spectroscopy (XPS) can be used to characterize elemental composition and elemental ratios of our materials. Optical properties of core and core-shell QDs (absorption and emission spectra and emission quantum efficiency) can be characterized using UV-Vis absorption and photoluminescence spectrophotometry.

An example of a process for producing semiconductor nanocrystals comprising InP and other inorganic III-V semiconductor materials is disclosed in U.S. Application No. 60/866,822, entitled “Nanocrystals Including A Group IIIa Element And A Group Va Element, Method, Composition, Device And Other Products”, filed 21 Nov. 2006 of Clough et al, which is hereby incorporated herein by reference in its entirety. InP with solution quantum yields reaching 50% or above may be achieved. Examples of other processes for preparing quantum dots comprising inorganic III-V semiconductor materials are disclosed in WO2006/076290, entitled “Nanocrystals Including III-V Semiconductors”, of Bawendi et al, published 20 Jul. 2006, which is hereby incorporated herein by reference in its entirety.

QDs can be included in devices by various deposition techniques. Examples include, but are not limited to, those described in International Patent Application No. PCT/US2007/08873, entitled “Composition Including Material, Methods Of Depositing Material, Articles Including Same And Systems For Depositing Material”, of Seth A. Coe-Sullivan, et al., filed 9 Apr. 2007, International Patent Application No. PCT/US2007/09255, entitled “Methods Of Depositing Material, Methods Of Making A Device, And Systems And Articles For Use In Depositing Material”, of Maria J, Anc, et al., filed 13 Apr. 2007, International Patent Application No. PCT/US2007/08705, entitled “Methods And Articles Including Nanomaterial”, of Seth Coe-Sullivan, et al, filed 9 Apr. 2007, International Patent Application No. PCT/US2007/08721, entitled “Methods Of Depositing Nanomaterial & Methods Of Making A Device” of Marshall Cox, et al., filed 9 Apr. 2007, U.S. patent application Ser. Nos. 11/253,612, entitled “Method And System For Transferring A Patterned Material” of Seth Coe-Sullivan, et al., filed 20 Oct. 2005, and U.S. patent application Ser. No. 11/253,595, entitled “Light Emitting Device Including Semiconductor Nanocrystals”, of Seth Coe-Sullivan, et al., filed 20 Oct. 2005. Each of the foregoing patent applications is hereby incorporated herein by reference in its entirety.

In certain embodiments, flexible substrates can be used to produce flexible devices. The combined ability to print colloidal suspensions of QDs over large areas and to tune their color over the entire visible spectrum makes them an ideal chromophore for solar cell applications that demand tailored color in a thin, light-weight package.

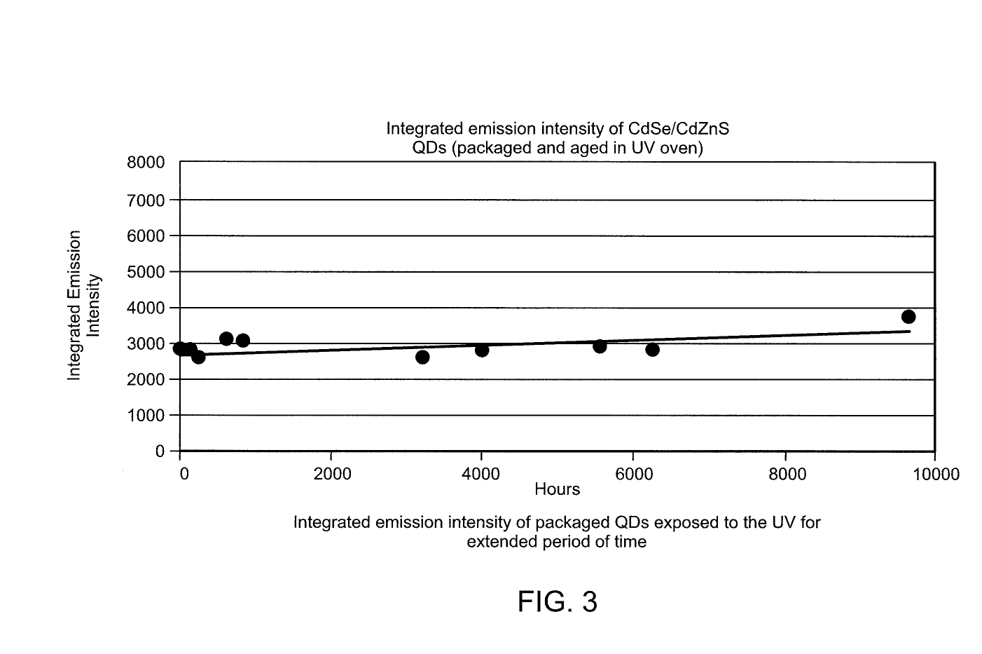

Data for intrinsic QD lifetimes under UV photo-luminescent stress conditions exceeding 10,000 hours and counting (with no significant change in brightness), is indicative of the great potential for these printable, inorganic semiconductor quantum dots. For reference, the integrated emission intensity of packaged CdeSe/CdZnS QDs aged in the UV oven is shown in FIG. 3.

For additional information relating to semiconductor nanocrystals and their use, see also U.S. Patent Application No. 60/620,967, filed Oct. 22, 2004, and 11/032,163, filed Jan. 11, 2005, U.S. patent application Ser. No. 11/071,244, filed 4 Mar. 2005. Each of the foregoing patent applications is hereby incorporated herein by reference in its entirety.

As used herein, “top” and “bottom” are relative positional terms, based upon a location from a reference point. More particularly, “top” means furthest away from the substrate, while “bottom” means closest to the substrate. For example, for a device that optionally includes two electrodes, the bottom electrode is the electrode closest to the substrate, and is generally the first electrode fabricated; the top electrode is the electrode that is more remote from the substrate, on the top side of the light-emitting material. The bottom electrode has two surfaces, a bottom surface closest to the substrate, and a top surface further away from the substrate. Where, e.g., a first layer is described as disposed or deposited “over” a second layer, the first layer is disposed further away from substrate. There may be other layers between the first and second layer, unless it is otherwise specified. For example, a cathode may be described as “disposed over” an anode, even though there are various organic and/or inorganic layers in between.

As used herein, the singular forms “a”, “an” and “the” include plural unless the context clearly dictates otherwise. Thus, for example, reference to a nanomaterial includes reference to one or more of such materials.

All the patents and publications mentioned above and throughout are incorporated in their entirety by reference herein. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. A photovoltaic device including a surface for receiving light energy and a heat transfer material positioned between a source of light energy and the surface for receiving light energy, wherein the heat transfer material comprises luminescent quantum dots dispersed in a host medium.

2. A photovoltaic device in accordance with claim 1 wherein the heat transfer material comprises a host medium comprising a liquid.

3. A photovoltaic device in accordance with claim 1 wherein the host medium comprises a heat transfer material.

4. A photovoltaic device in accordance with claim 2 wherein the liquid comprises a heat transfer fluid.

5. A photovoltaic device in accordance with claim 4 wherein the heat-transfer fluid further includes a non-polar molecules to tune viscosity.

6. A photovoltaic device in accordance with claim 1 wherein at least a portion of the quantum dots include one or more ligands attached to a surface thereof.

7. A photovoltaic device in accordance with claim 6 wherein the one or more ligands comprise alkyl-amines, thiols, or mild alkyl chain based acids.

8. A photovoltaic device in accordance with claim 1 wherein the quantum dots comprise InAsₓP₁₋ₓ, wherein 0≦x≦1.

9. A photovoltaic device in accordance with claim 1 wherein at least a portion of the quantum dots comprise a core comprising a first semiconductor material and a shell disposed over at least a portion of a surface of the core, wherein the shell comprises a second semiconductor material.

10. A photovoltaic device in accordance with claim 9 wherein the core comprises InAsₓP₁₋ₓ, wherein 0≦x≦1.

11. A photovoltaic device in accordance with claim 9 wherein the shell comprises ZnSeS.

12. A photovoltaic device in accordance with claim 9 wherein the shell comprises ZnS.

13. A photovoltaic device in accordance with claim 12 wherein the one or more ligands comprise alkyl-amines, thiols, or mild alkyl chain based acids.

14. A photovoltaic device in accordance with claim 1 wherein the quantum dots are capable of emitting light at a predetermined wavelength in a range from 780 nm to 1000 nm.

15. A photovoltaic device in accordance with claim 14 wherein the quantum dots do not include cadmium, lead, or other heavy metal.

16. A photovoltaic device useful for solar energy conversion including a surface for receiving light energy, a layer comprising a quantum dot down-conversion material disposed over at least a portion of the surface for receiving light energy, and a heat transfer material positioned between a source of light energy and the layer, wherein the heat transfer material comprises luminescent quantum dots dispersed in a host medium.

17. A solar cell comprising a photovoltaic device in accordance with claim 1.

18. A heat transfer material comprising a quantum dot down-conversion material comprising quantum dots dispersed in a host medium.

19. A heat transfer material in accordance with claim 18 wherein the host material comprises a heat transfer fluid.

20. A heat transfer material in accordance with claim 18 wherein the heat-transfer fluid further includes a non-polar molecules to tune viscosity.

21. A heat transfer material in accordance with claim 18 wherein at least a portion of the quantum dots include one or more ligands attached to a surface thereof.

22. A heat transfer material in accordance with claim 21 wherein the one or more ligands comprise alkyl-amines, thiols, or mild alkyl chain based acids.

23. A heat transfer material in accordance with claim 21 wherein the quantum dots comprise InAsₓP₁₋ₓ, wherein 0≦x≦1.

24. A heat transfer material in accordance with claim 21 wherein at least a portion of the quantum dots comprise a core comprising a first semiconductor material and a shell disposed over at least a portion of a surface of the core, wherein the shell comprises a second semiconductor material.

25. A heat transfer material in accordance with claim 24 wherein the core comprises InAsₓP₁₋ₓ, wherein 0≦x≦1.

26. A heat transfer material in accordance with claim 24 wherein the shell comprises ZnSeS.

27. A heat transfer material in accordance with claim 25 wherein the shell comprises ZnS.

28. A heat transfer material in accordance with claim 27 wherein the one or more ligands comprise alkyl-amines, thiols, or mild alkyl chain based acids.

29. A heat transfer material in accordance with claim 21 wherein the quantum dots are capable of emitting light at a predetermined wavelength in a range from 780 nm to 1000 nm.

30. A heat transfer material in accordance with claim 21 wherein the quantum dots do not include cadmium, lead, or other heavy metal.

31. A solar cell comprising a heat transfer material in accordance with claim 18.

32. A photovoltaic device in accordance with claim 4 wherein the heat transfer material is included in a thermosiphon positioned between a source of light energy and the surface for receiving light energy.

33. (canceled)
